(19) United States
(12) Patent Application Publication
(10) Pub. No.: US 2008/0083990 A1
(43) Pub. Date: Apr. 10, 2008

(54) SEMICONDUCTOR DEVICE AND METHOD OF MANUFACTURING THE SAME

(75) Inventors: Akitsugu Hatazaki, Yokkaichi (JP); Jota Fukuhara, Yokkaichi (JP); Tomio Katata, Yokkaichi (JP); Junichi Wada, Yokohama (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/843,995

(22) Filed: Aug. 23, 2007

(30) Foreign Application Priority Data
Oct. 5, 2006 (JP) 2006-274079

(51) Int. Cl. H01L 23/52; H01L 21/4763

(52) U.S. Cl. 257/751; 438/637; 257/E23.141; 257/E21.495

(57) ABSTRACT

A semiconductor device including a copper layer, an aluminum containing layer, and a barrier metal layer having a laminated structure of a titanium layer and a titanium oxide layer formed between the copper layer and the aluminum containing layer.

### CROSS-REFERENCE TO RELATED APPLICATIONS

This application is based upon and claims the benefit of priority from the prior Japanese Patent Application No. 2006-274079, filed on, Oct. 5, 2006 the entire contents of which are incorporated herein by reference.

### FIELD

The present disclosure is directed to a semiconductor device including an aluminum containing layer, and a method of manufacturing such semiconductor device.

### BACKGROUND

As disclosed in JP 2004-119754 A, employing aluminum (Al) containing layer as an interconnect layer for connecting each electrical component has become the mainstream approach in a typical semiconductor device such as a NAND flash memory device. According to the manufacturing method disclosed in JP 2004-119754 A, for example, an insulating film is formed on a silicon substrate; a contact hole is defined in the insulating film; a titanium (Ti) layer is formed inside the contact hole and on the insulating film; oxygen is introduced into the Ti layer; a titanium nitride (TiN) layer is formed on the Ti layer surface; a TiO₂ layer is formed under the TiN layer by thermal processing of the TiN layer and the Ti layer; the TiN layer is removed; and aluminum alloy layer is formed on the TiO₂ layer and inside the contact hole. Increase in contact resistance is witheld by such arrangement.

However, employing the above described aluminum containing layer as an interconnect layer brings rise to a problem concerning elevation in resistance of the Al containing layer caused by reciprocal diffusion between copper (Cu) and aluminum (Al) when a Cu layer and the Al containing layer are in structural contact.

### SUMMARY

The present disclosure provides a semiconductor device which is arranged to restrain elevation in resistance caused by Cu—Al reciprocal diffusion occurring when connecting a Cu layer and an Al containing layer and a method of manufacturing such semiconductor device.

In one aspect of the present disclosure, a semiconductor device includes a copper layer; an aluminum containing layer; and a barrier metal layer having a laminated structure of a titanium layer and a titanium oxide layer formed between the copper layer and the aluminum containing layer.

In another aspect, a semiconductor device includes a copper layer; an aluminum containing layer; and a barrier metal layer having a laminated structure of a tantalum layer and a tantalum oxide layer or a niobium layer and a niobium oxide layer formed between the copper layer and the aluminum containing layer.

Yet, in another aspect, a method of manufacturing a semiconductor device includes forming a copper layer; forming an interlayer insulating film on the copper layer; defining a hole penetrating to a top of the copper layer in the interlayer insulating film; forming a barrier metal layer inside the hole by forming a base layer including at least either titanium, tantalum or niobium, and oxidating the base layer; and forming an aluminum containing layer on the barrier metal layer.

Yet, further in another aspect, a method of manufacturing a semiconductor device includes forming a copper layer; forming an interlayer insulating film on the copper layer; defining a hole penetrating to a top of the copper layer in the interlayer insulating film; forming a base layer including at least titanium inside the hole; forming a titanium oxide layer by oxidating the base layer; forming a titanium nitride layer on the titanium oxide layer; forming a titanium layer on the titanium nitride layer; and forming an aluminum containing layer on the titanium layer.

### BRIEF DESCRIPTION OF THE DRAWINGS

Other objects, features and advantages of the present disclosure will become clear upon reviewing the following description of the embodiment of the present disclosure with reference to the accompanying drawings, in which,

FIG. 1 illustrates a portion of an electrical configuration of a memory cell region indicating one embodiment of the present disclosure;

FIG. 2 is a schematic plan view illustrating a peripheral structure of a source line contact region;

FIG. 3 is a schematic cross sectional view taken along line 3-3 of FIG. 2;

FIG. 4 is a schematic cross sectional view taken along line 4-4 of FIG. 2 and line 4-4 of FIG. 6;

FIG. 5 is a schematic cross sectional view taken along line 5-5 of FIG. 2 and line 5-5 of FIG. 6;

FIG. 6 is a schematic cross sectional view taken along line 6-6 of FIG. 2;

FIGS. 7 to 11 schematically illustrate a layered structure of a barrier metal layer (part 1 to part 5);

FIG. 12A is a schematic cross sectional view taken along line 5-5 and line 4-4 of FIG. 2 undergoing a manufacturing process;

FIG. 12B is a schematic cross sectional view taken along line 3-3 of FIG. 2 undergoing a manufacturing process; and

FIGS. 13 to 18 is a schematic cross sectional view taken along line 5-5 of FIG. 2 undergoing a manufacturing process (part 2 to part 7); and

FIGS. 19 to 29 is a schematic cross sectional view taken along line 4-4 of FIG. 2 undergoing a manufacturing process (part 2 to part 12).

### DETAILED DESCRIPTION

One embodiment employing the semiconductor device and its manufacturing method of the present disclosure to a NAND flash memory device and its manufacturing method will be described hereinafter with reference to the drawings. More specifically, the present disclosure is employed to a memory cell region of the NAND flash memory device assuming a multi-layer interconnect structure in the upper layers thereof. References will be made to the elements indicated in the drawings with the same or a similar reference symbol when referring to the same element or a similar element. However, the drawings are merely schematic and do not reflect the actual correlation between thickness and planar dimension and percentage ratio of thickness between each layer.

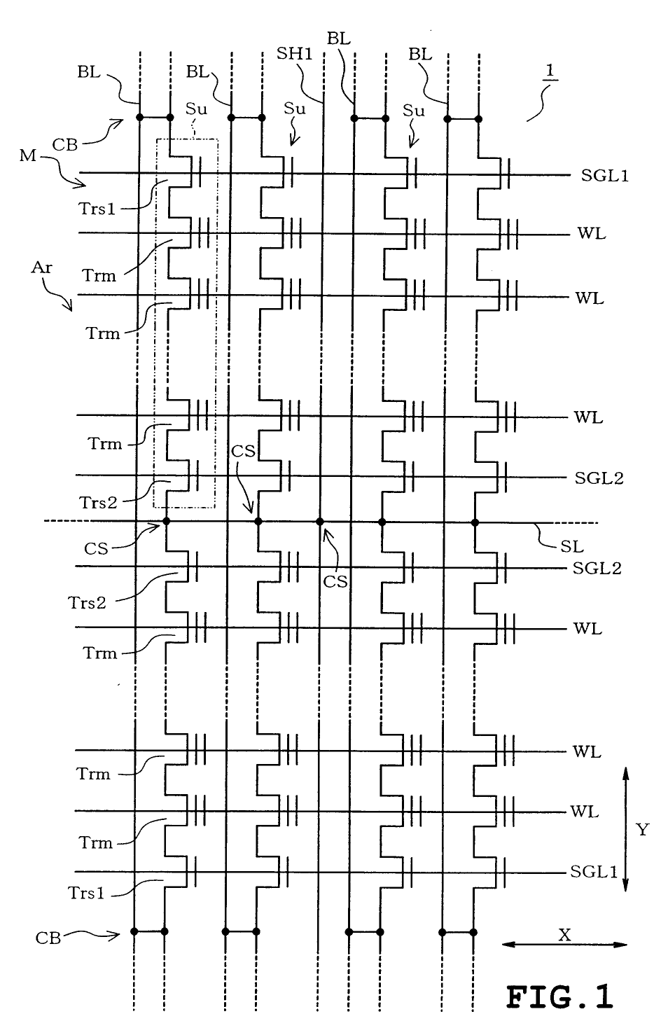

FIG. 1 illustrates a portion of an equivalent circuit of a memory cell array in a memory cell region of the NAND flash memory.

A memory cell array Ar in a memory cell region M of the NAND flash memory device 1 comprises NAND cell units Su arranged in an array of rows and columns. The NAND cell unit Su is constituted by two select gate transistors Trs1 and Trs2, and a plurality (eight for example: nth power of 2 (n is a positive integer)) of memory cell transistors Trm connected in series to the select gate transistors Trs1 and Trs2. The plurality of neighboring memory cell transistors Trm shares source/drain regions within a single NAND cell unit Su.

Referring to FIG. 1, the memory cell transistors Trm aligned in an X-direction (word line direction, gate-width direction) are connected to a common word line (control gate line) WL. Also, the select gate transistors Trs1 aligned in the X-direction in FIG. 1 are connected to a common select gate line SGL1. Similarly, the select gate transistors Trs2 are connected to a common select gate line SGL2, extending in the X-direction in FIG. 1.

A bit-line contact CB is connected to the drain region of the select gate transistor Trs1. The bit line contact CB is connected to a bit line BL extending in a Y-direction (gate-length direction, bit-line direction) perpendicularly intersecting the X-direction as viewed in FIG. 1. Also, the select gate transistors Trs2 are connected to a source line SL extending in the X-direction as viewed in FIG. 1 via the source region.

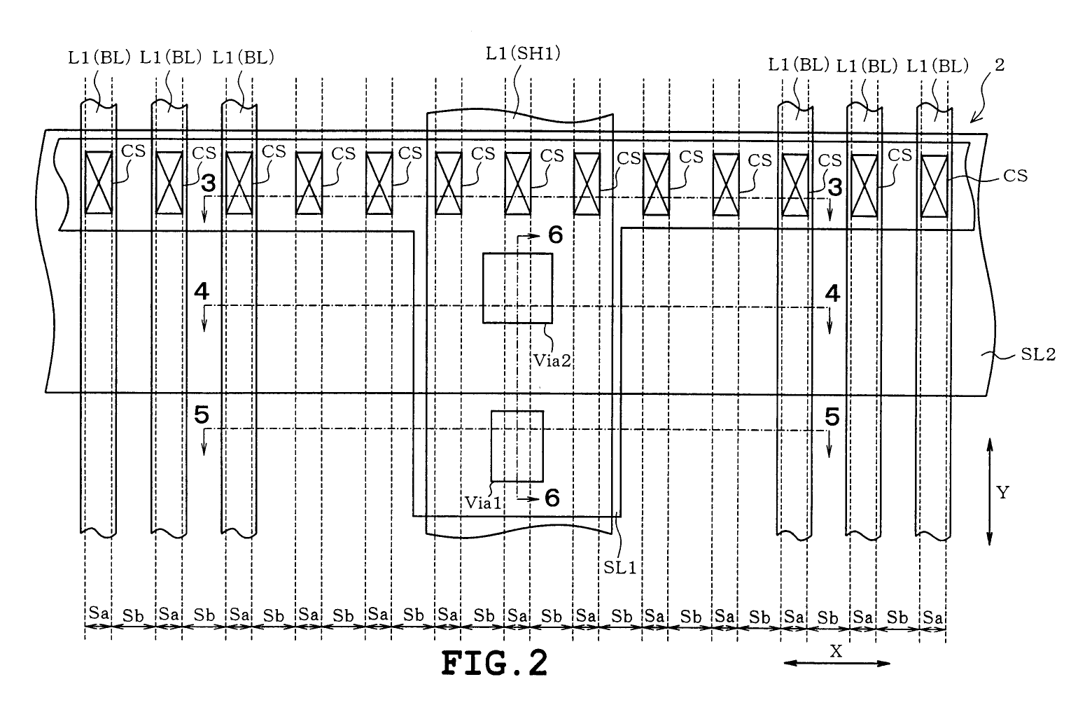

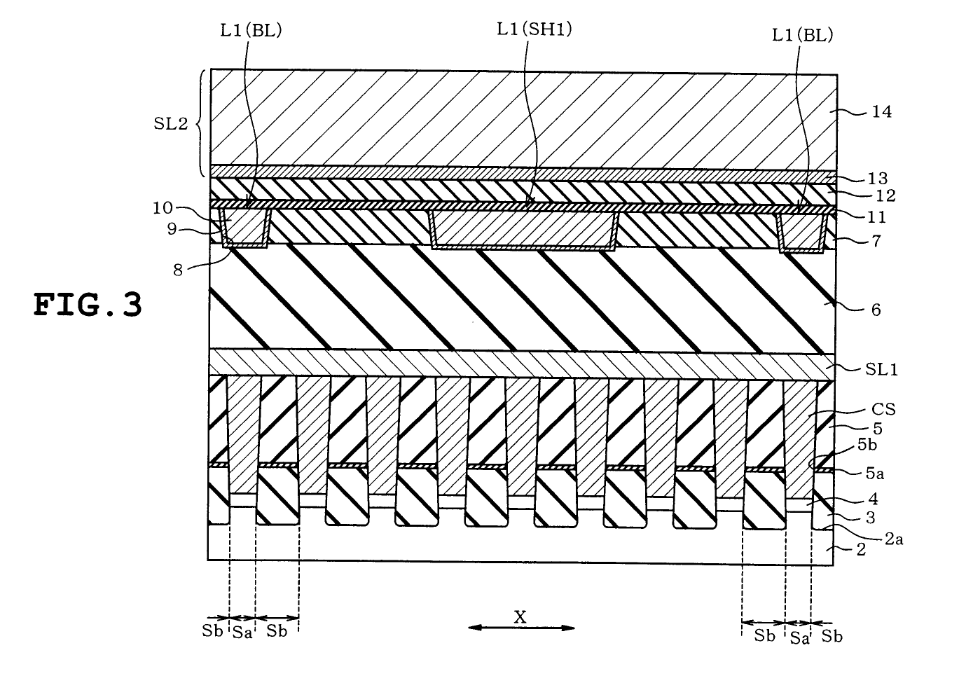

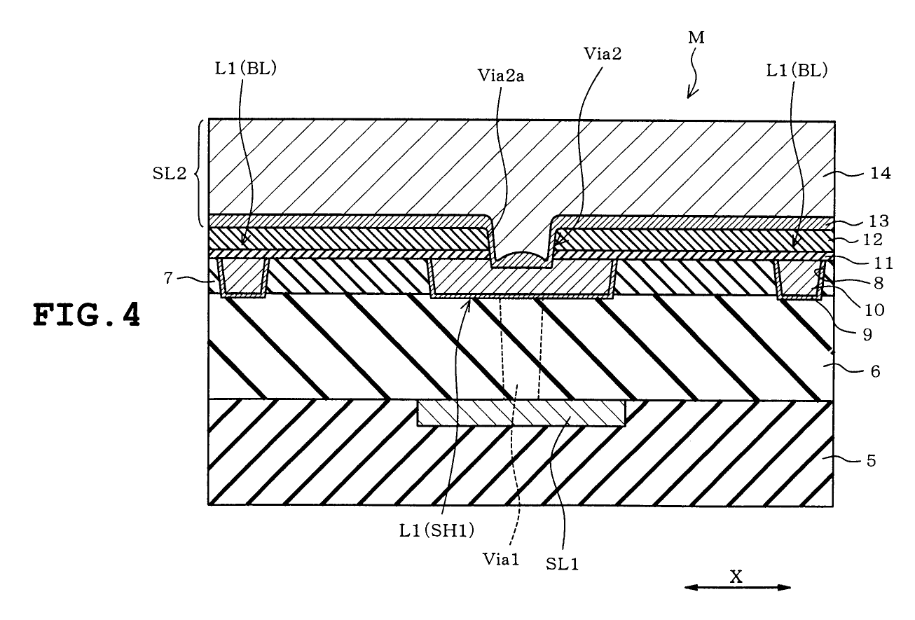

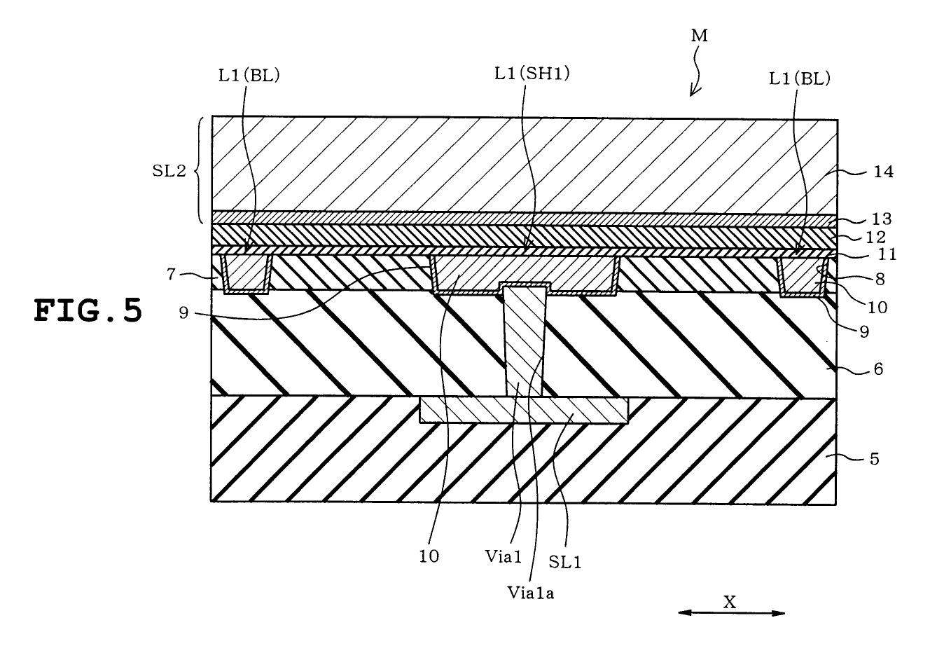

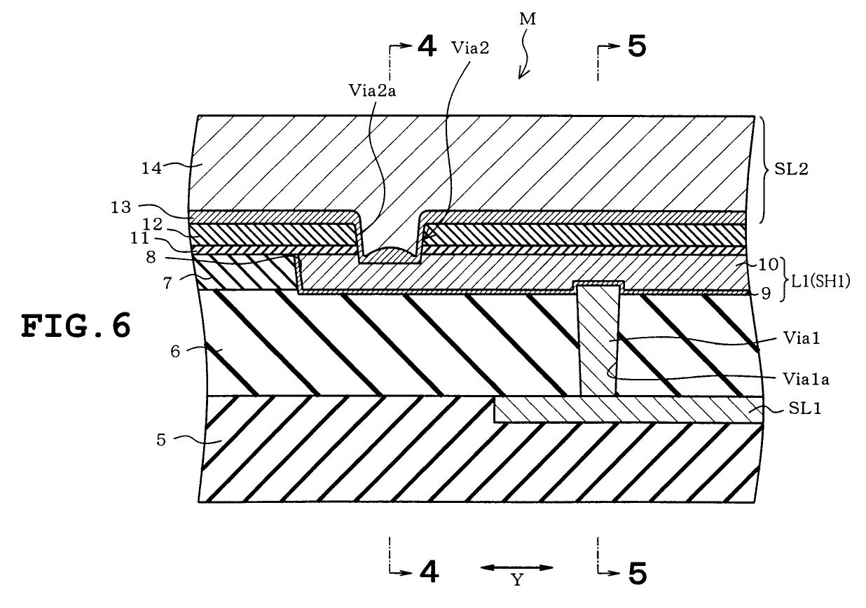

FIG. 2 is a plan view illustrating a layout pattern of a portion of the memory cell region and FIG. 3 is a schematic vertical cross section taken along line 3-3 (X-direction) of FIG. 2. FIG. 6 is a schematic vertical cross section taken along line 6-6 of FIG. 2. Also, FIG. 4 is a schematic vertical cross section taken along line 4-4 of FIGS. 2 and 6. Also, FIG. 5 is a schematic vertical cross section taken along line 5-5 (X-direction) of FIGS. 2 and 6.

Referring to FIG. 2, the p-type silicon substrate 2 serving as a semiconductor substrate has element isolation regions Sb assuming an STI (Shallow Trench Isolation) structure defined along the Y-direction as viewed in FIG. 2. A plurality of element isolation regions Sb are formed at predetermined intervals in the X-direction, whereby element regions (active area) Sa are isolated.

Referring to FIG. 3, the silicon substrate 2 has element isolation trenches 2a defined on the surface layer thereof along the Y-direction. A plurality of element isolation trenches 2a are defined in the X-direction and each element isolation trench 2a is filled with an element isolation insulating film 3 respectively. These pluralities of element isolation insulating films 3 constitute the element isolation regions Sb that divide the element region Sa in the surface layer of the silicon substrate surface 2 in to plurality of sections.

Each of the plurality of element regions Sa of the silicon substrate 2 has formed thereto an n-type impurity doping layer (diffusion layer) 4. Also, an interlayer insulating film 5 is formed on the element isolation insulating film 3 via a barrier film 5a.

An upwardly oriented contact hole 5b is defined in the interlayer insulating film 5 from the upper surfaces of the respective n-type impurity doping layers 4 (silicon substrate 2). A source line contact CS is filled in each of the contact holes 5 of the interlayer insulating film 5. These source line contacts CS are dimensioned in identical diameters respectively as shown in FIGS. 2 and 3 and are aligned at predetermined intervals in the X-direction. The first metal interconnect SL1 is formed as a first source line establishing a connection across the tops of these source line contacts CS.

Referring to FIGS. 4 and 6, the upper surface of the first metal interconnect SL1 is formed on substantially coplanar with the upper surface of the interlayer insulating film 5. Though the height of the upper surface of the interlayer insulating film 5 and the height of the upper surface of the first metal interconnect SL1 are coplanar as viewed in the drawings (FIGS. 4 to 6), they are unleveled in the actual product. Thus, substantially coplanar surface is defined to include unleveled surfaces.

Referring to FIGS. 3 and 6, an interlayer insulating film 6 is formed on the first metal interconnect SL1. Referring to FIGS. 5 and 6, a via-hole Via1a is defined in the interlayer insulating film 6 and via-plug Via1 is filled inside the via-hole Via1a. The upper surface of the interlayer insulating film 6 and the upper surface of the via-plug Via1a are substantially coplanar.

As can be seen in FIG. 2, via-plug Via1 is formed in areas where no source line contact CS exists thereunder. In other words, the source line contact CS is formed in an area where no via-plug Via1 exists thereabove.

An interlayer insulating film 7 is formed on the interlayer insulating film 6. The interlayer insulating film 7 has long holes 8 defined thereto along the Y-direction. The long holes 8 are aligned in the X-direction and are each filled with second metal interconnect L1. The second metal interconnect L1 each assume a linear structure extending along the Y-direction. Each second metal interconnect L1 is configured so that its underside is positioned above the underside of the interlayer insulating film 6 and slightly below the upper surface of the interlayer insulating film 6.

The second metal interconnects L1 can be distinguished by functionality to: source shunt lines SH1 and bit lines BL. The bit lines BL are disposed at both sides of the source shunt line SH1 with spacing from the source shunt line SH1 and in the same layer as the source shunt line SH1. Referring to FIGS. 5 and 6, the source shunt line SH1 is configured so that its underside X-directional width and Y-directional width are both wider than the upper surface width of the via-plug Via1, thus increasing the contact area of the via-plug Via1 by covering the entire upper surface and the upper side-face of the via-plug Via1. Hence, the source shunt line SH1 reliably energizes the first metal interconnect SL1 (first source line) and the later described second source line SL2. Referring to FIGS. 2 and 5, the bit line BL is configured so that its X-directional width is narrow compared to the X-directional width of the source shunt line SH1.

The second metal interconnect L1 is configured by a barrier metal layer 9 and a metal layer 10 having its side surface and underside covered by the barrier metal layer 9. The metal layer 10 is composed of copper (Cu) material.

The upper surface of the interlayer insulating film 7 and the upper surfaces of the plurality of second metal interconnects L1 are formed substantially coplanar. The drawings (FIGS. 3 to 6) illustrate the upper surface height of the interlayer insulating film 7 to be coplanar with the upper surface height of the plurality of second metal interconnects L1; however, the upper surfaces are unleveled in the actual product.

Referring to FIGS. 3 to 6, a cap film 11 is formed on the interlayer insulating film 7 and the plurality of second metal interconnects L1, and an interlayer insulating film 12 is formed on the cap film 11. The cap film 11 is composed of a silicon nitride film, for example. The interlayer insulating film 12 is composed of a silicon oxide film, for example.

Referring to FIGS. 4 and 6, a via hole Via2a is formed in the cap film 11 and the interlayer insulating film 12 so as to penetrate to the top of the source shunt line SH1. The via hole Via2a is filled with the via plug Via2. The via plug Via2 is configured so that its underside X-directional width and Y-directional width are both narrower than the X-directional width and Y-directional width of the upper surface of the source shunt line SH11.

The via plug Via2 is composed of a barrier metal layer 13 and a metal layer 14 having its underside covered by the barrier metal layer 13. The metal layer 14 is formed in the inner side of the barrier metal layer 13 by aluminum (Al) material. The barrier metal layer 13 and the metal layer 14 constitute the via plug Via2 and function as a second source line SL2 as well. The multi-layer interconnect structure is configured as thus described.

The features of the present embodiment lies in the material constituting the barrier metal layer 13 provided between copper (Cu) constituting the metal layer 10 of the source shunt line SH1 and aluminum (Al) constituting the metal layer 14, thus a detailed description of the material will be given hereinafter.

Conventionally, employing a three-layer structure composed of titanium (Ti), titanium nitride (TiN), and Ti and a single Ti layer structure have been conceived for the barrier metal layer 13. However, employing Cu material as metal layer 10 and Al material as metal layer 14 caused increase in resistance due to reciprocal diffusion between the metal layer 10 and Al material constituting the metal layer 14 serving as a reflow layer. The inventors have found that Ti/TiN/Ti layer structure does not provide sufficient barrier, thus have been exploring the appropriate material for the barrier metal layer 13.

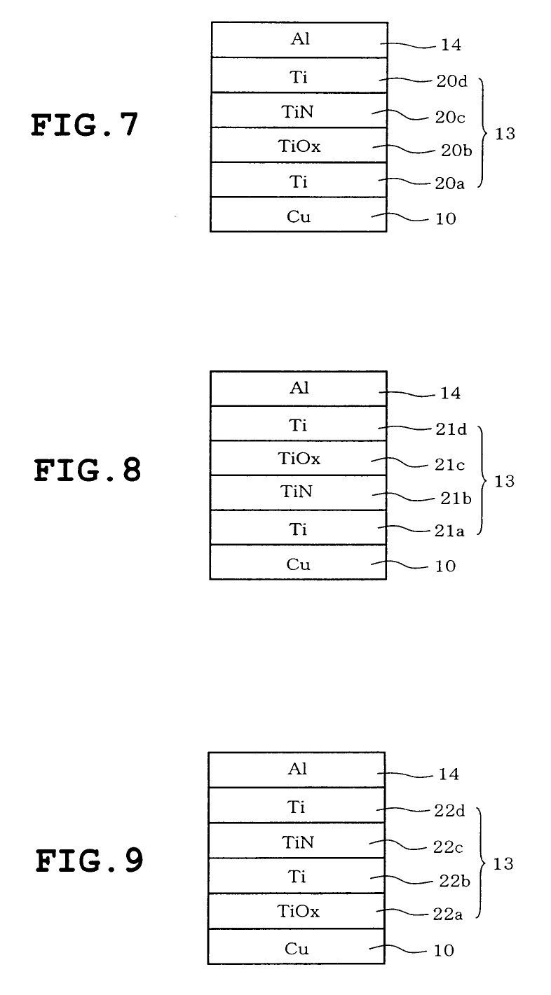

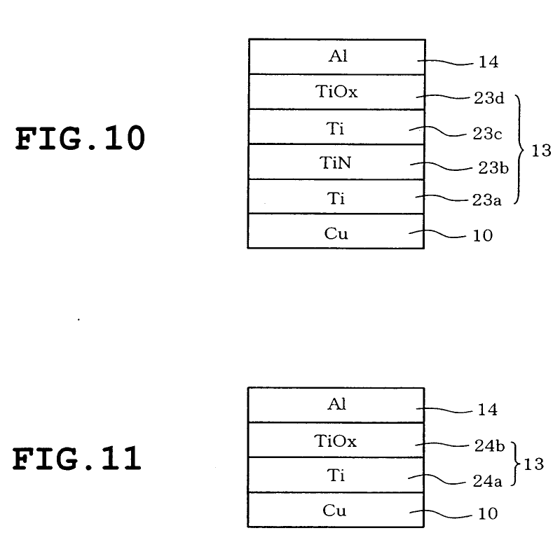

As a result of exploration, it has been found that employing a laminated structure of Ti layer and titanium oxide (TiOx) as the barrier metal layer 13 brings increase in barrier capacity. That is, employing the laminated structure prevents increase in interconnect resistance due to Cu—Al reciprocal diffusion occurring upon connecting Cu material and Al material. The present embodiment employs the following laminated structure (listed in sequence from the metal layer 10 in the lower layer to the metal layer 14 in the upper layer) as illustrated in FIGS. 7 to 11, in which FIG. 7 indicates (1) Ti layer 20a/TiOx layer 20b/TiN layer 20c/TiX layer 20d; (2) FIG. 8, Ti layer 21a/TiN layer 21b/TiOx layer 21c/Ti layer 21d; (3) FIG. 9, TiOx layer 22a/Ti layer 22b/TiN layer 22c/Ti layer 22d; (4) FIG. 10, Ti layer 23a/TiN layer 23b/Ti layer 23c/TiOx layer 23d; and FIG. 11, (5) Ti layer 24a/TiOx layer 24b.

The inventors have obtained the following outcome in measurement of the reflection ratio of light radiating from the Al material side that constitute the metal layer 14 when reflection ratio of light reflected on the surface of the silicon material is set at 100%. The reflection ratio of structures (1) and (2) indicated 226% whereas structures (3), (4) and (5) indicated 213% which is an indication that considering the planarity of Al material, structure (1) or (2) is preferable to structures (3), (4) and (5).

Also, in case structure (2) is employed, the TiOx layer 21c immediately below the Ti layer 21d may risk being reduced by aluminum material in the metal layer 14 upper layer. Taking such effect into consideration, the TiN layer 20c and the Ti layer 20d may be provided between the metal layer 14 and the TiOx layer 20b as indicated in structure (1) rather than structure (2).

According to the present embodiment, the barrier metal layer 13 is formed on the Cu material constituting the metal layer 10 and Al material constituting the metal layer 14 is formed on the barrier metal layer 13. Furthermore, the barrier metal layer 13 assumes a layered structure including the TiOx layer 20b, 21c, 22a, 23d or 24d. Thus, increase in interconnect resistance due to Cu—Al reciprocal diffusion occurring upon Cu material and Al material connection can be prevented.

Referring to FIG. 7, a further enhanced property can be obtained when the barrier metal layer 13 is formed on the metal layer 10 in the sequence of Ti layer 20a/TiOx layer 20b/TiN layer 20c/Ti layer 20d.

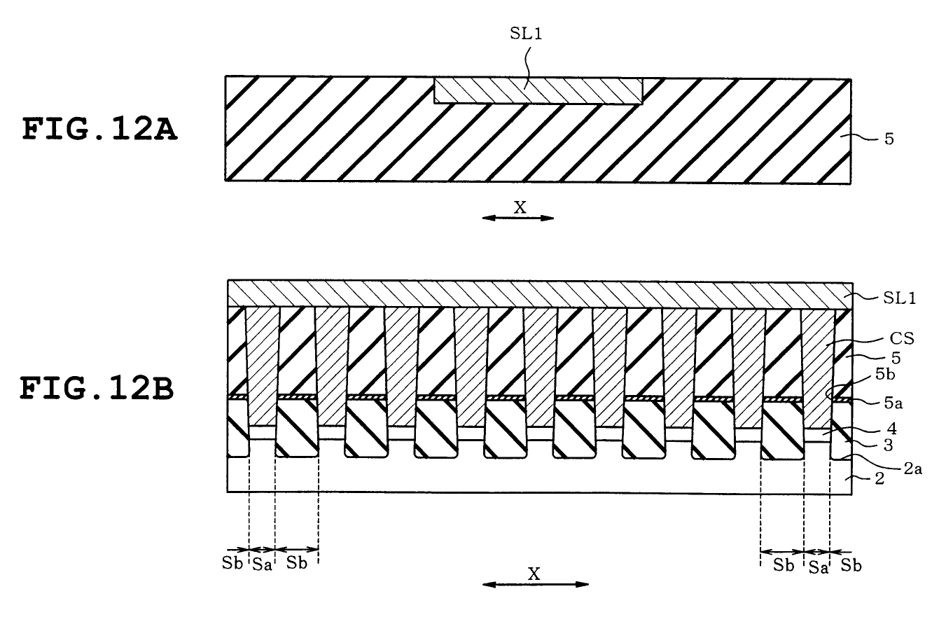

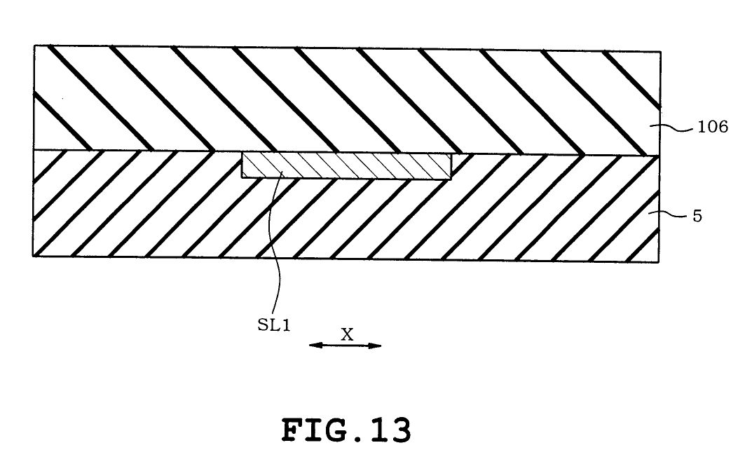

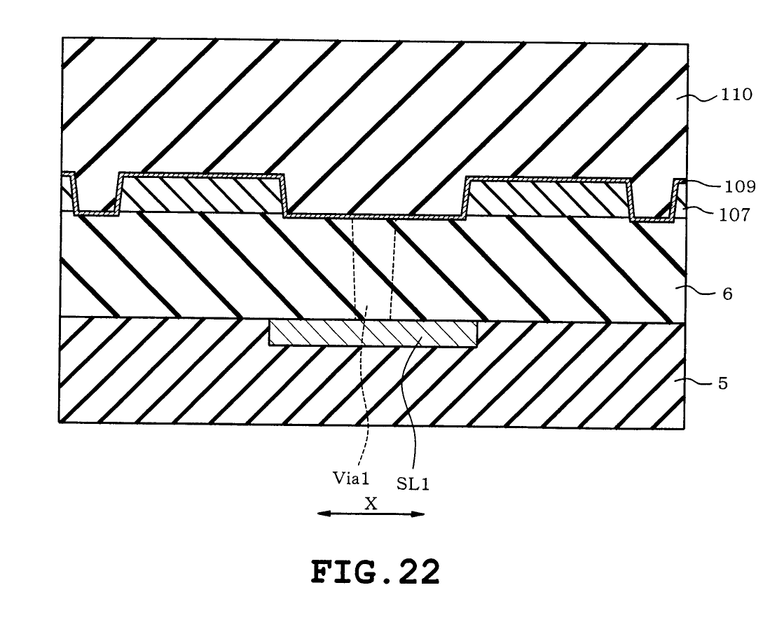

A manufacturing method in accordance with the present embodiment will be described with reference to FIGS. 12A to 29. Though the description will focus on the features of the present embodiment, the later described steps may be eliminated as required and well known steps and steps to form other regions not shown may be added as required.

For ease of description, the elements of manufacture (referred to as manufacture elements hereinafter) that correspond to the elements of each film and each layer (referred to as structural elements hereinafter) will be identified, on a required basis, by reference symbols of manufacture elements having 100 added to the reference symbols of the structural elements.

The features of the present embodiment lies in the manufacturing method of the barrier metal layer 13, thus, only a brief description of the manufacturing method will be given on the structure below the via plug Via1. FIG. 12A schematically indicates the cross sections taken along lines 4-4 and 5-5 of FIG. 2 when manufacture of FIG. 2 is in-process. FIG. 12B schematically indicates the cross sections taken along lines 3-3 of FIG. 2 when manufacture of FIG. 2 is in-process.

Referring to FIG. 12B, a plurality of n-type diffusion layers (impurity doping region) 4, constituting the source regions in the surface layer of the silicon substrate 2, is aligned in the X-direction. Each of the plurality of diffusion layer 4 has a source line contact CS projecting upward from the surface of the silicon substrate 2. Referring to FIGS. 12A and 12B, the first metal interconnect layer SL1 serving as the first source line is formed over across the plurality of source line contacts CS. The first metal interconnect SL 1 is formed on the upper portion of the interlayer insulating film 5 by damascene process.

Referring to FIG. 12A, the upper surface of the first metal interconnect SL1 is planarized and formed at level with the upper surface of the interlayer insulating film 5. The expression “at level” denotes being substantially at level and is inclusive of any marginal error or tolerance that may occur in the actual manufacture. Also, “planar” denotes the state of being substantially at level and is inclusive of unevenness of some magnitude, curvature, or the like. The above described definition is valid in the descriptions hereinafter.

FIGS. 13 to 18 schematically illustrate the cross section taken along line 5-5 of FIG. 2 when manufacture of FIG. 2 is in-process. As illustrated in FIG. 13, a TEOS-based or a SiH₄ based silicon oxide film 106 is formed on the interlayer insulating film 5 and the first metal interconnect SL1 by HDP-CVD process, for example.

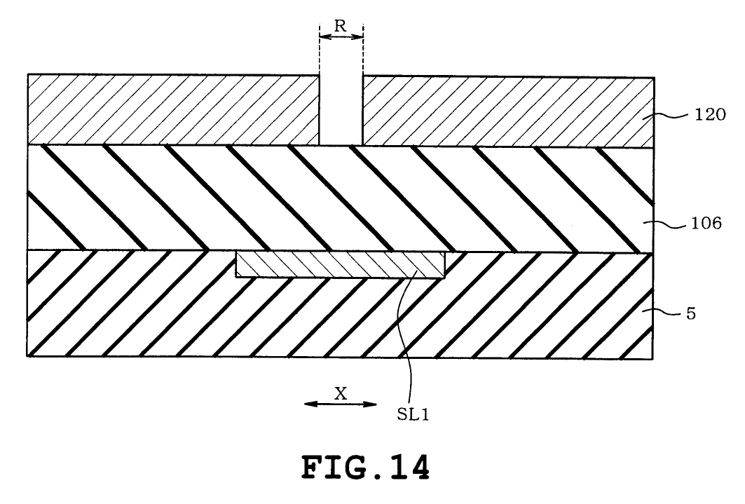

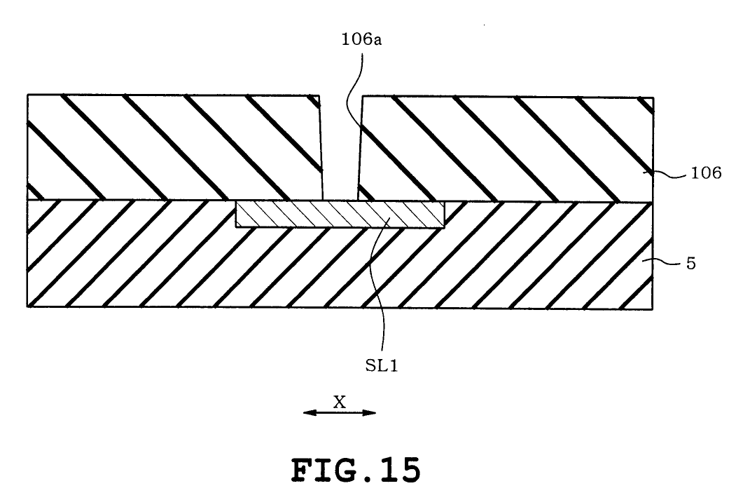

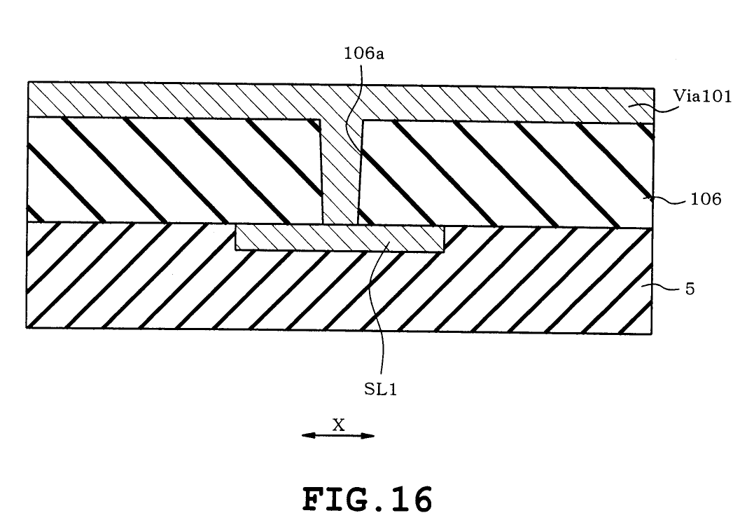

Next, as illustrated in FIG. 14, a resist 120 is coated on the silicon oxide film 106 and thereafter patterned. An opened region R of the resist 120 is provided in the region above the first metal interconnect SL1.

Next, as illustrated in FIG. 15, using the patterned resist 120 as a mask, the silicon oxide film 106 is etched by RIE (Reactive Ion Etching) process to define a hole 106a that penetrates to the upper surface of the first metal interconnect SL1. Next, wet etch is performed by using phosphorous.

Next, as illustrated in FIG. 16, the hole 106 is filled with a plugging material Via 101. When filling the plugging material Via 101, a barrier metal layer (not shown) composed of TiN material is formed isotropically in small thickness along the inner surface of the hole 106a, the upper surface of the first metal interconnect SL1, and the upper surface of the silicon oxide film 106. Then, a metal layer (not shown) composed of tungsten is formed inside the hole 106a; more specifically, in the inner side of the barrier metal layer and on the barrier metal layer on the upper surface of the silicon oxide film 106.

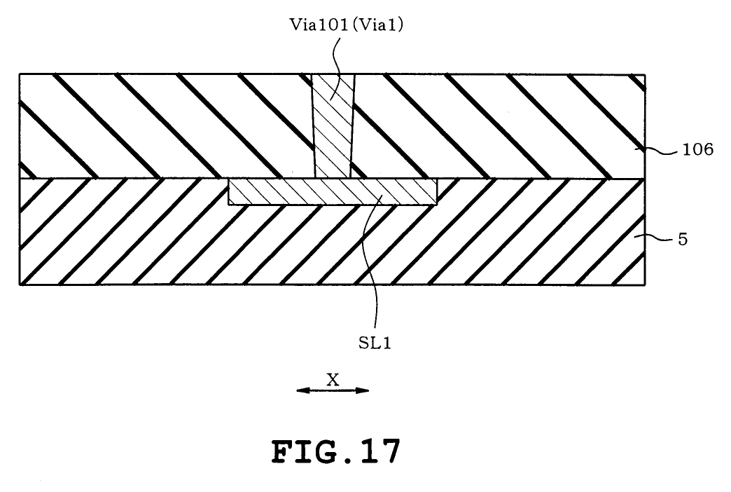

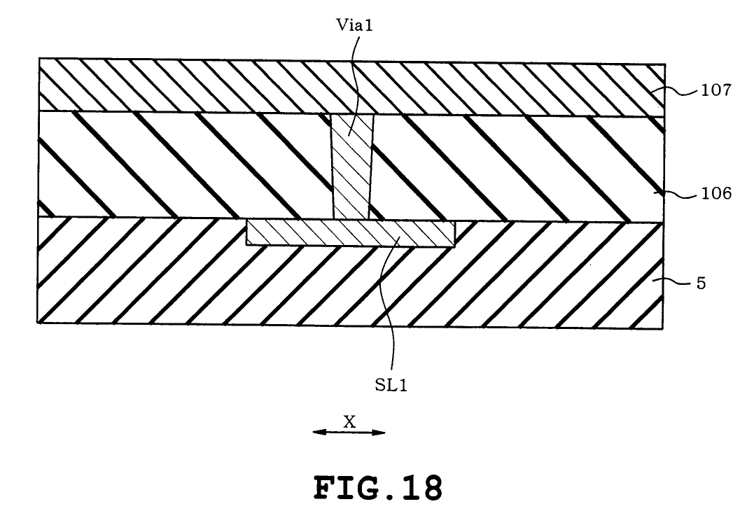

Next, as illustrated in FIG. 17, the upper surfaces of the plugging material Via 101 and the silicon oxide film 106 is planarized by CMP (Chemical Mechanical Polishing) process. At this point, the upper surface of the silicon oxide film 106 is removed by a predetermined film thickness (in the order of tens of nm, for example). The planarizing process planarizes the upper surface of the plugging material Via 101 to be coplanar with the upper surface of the silicon oxide film 106. After such steps, the via plug Vial can be formed inside the silicon oxide film 106 by damascene process. Next, as illustrated in FIG. 18, a TEOS-based silicon oxide film 107 is formed on the silicon oxide film 106 and the via plug Vial in the thickness of approximately 100 nm, for example.

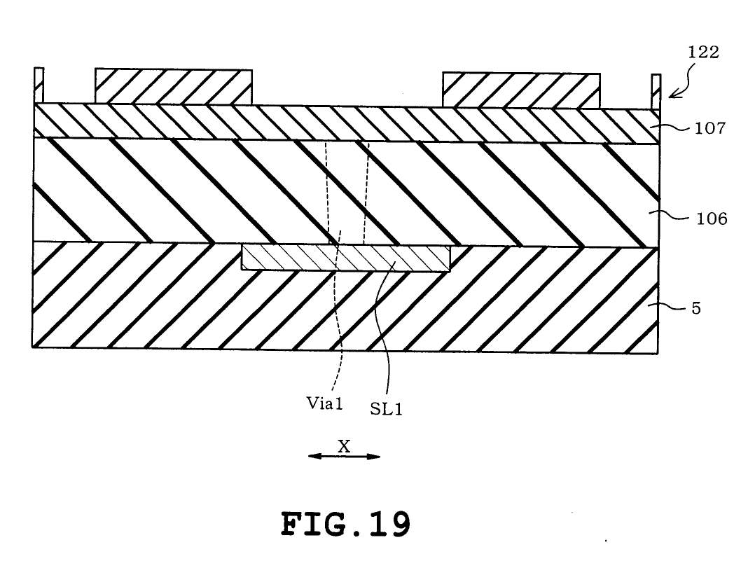

FIGS. 19 to 29 schematically illustrate the cross section taken along line 4-4 in FIG. 2 when manufacturing of FIG. 2 is in-process. Next, as shown in FIG. 19, a resist 122 is coated on the silicon oxide film 107 and the resist 122 is thereafter patterned. At this time, an opening (space pattern) for a resist pattern having greater width than the X-directional width of the upper surface of the via plug Via1 is provided above the via plug Via1 and line patterns are provided at two neighboring sides thereof.

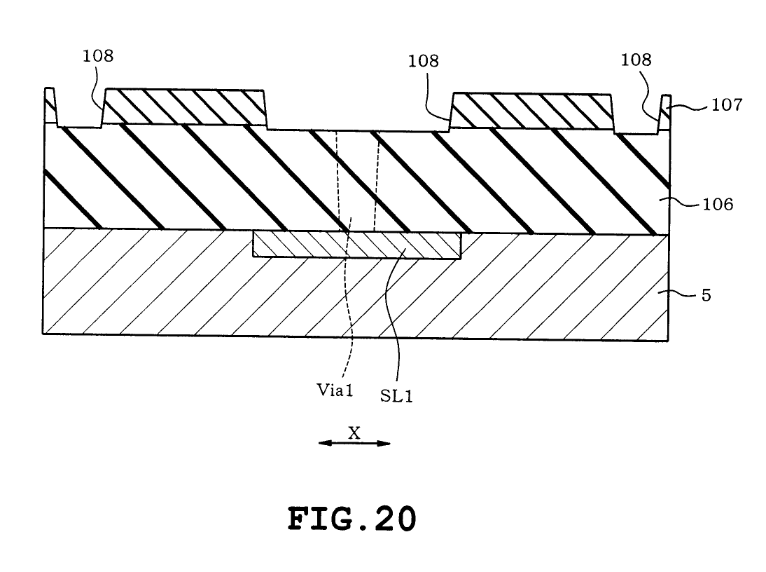

Next, as shown in FIG. 20, silicon oxide film 107 is removed by RIE process by using the patterned resist 122 as a mask. Thus, a plurality of linear long holes 108 extending in the Y-direction are aligned on the silicon oxide film 106 in the X-direction. Next, a wet-etch process is performed with phosphorous.

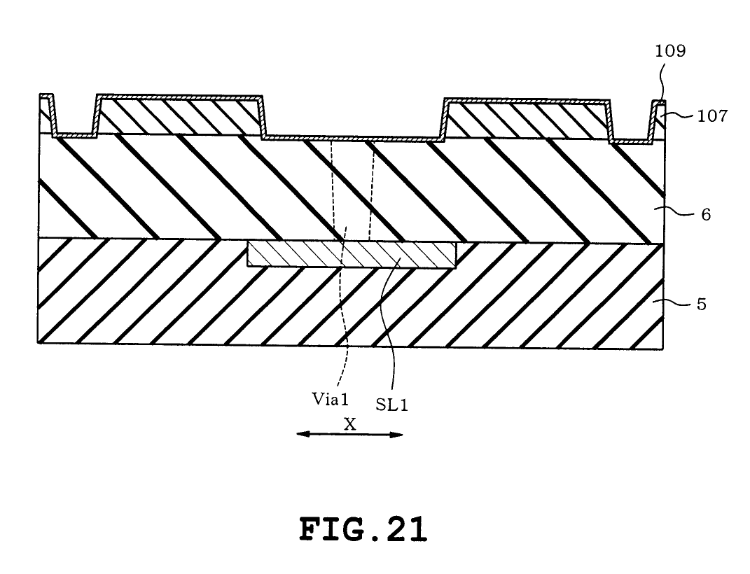

Next, as illustrated in FIG. 21, a barrier metal layer 109 is formed by sputtering process in thin film thickness along the inner surface of the long hole 108. More specifically, the barrier metal layer 109 composed of Ti is formed along the side-wall surface of the silicon oxide film 107 and the upper surface of the silicon oxide film 106 in thin film thickness of 10 nm, for example, by sputtering process.

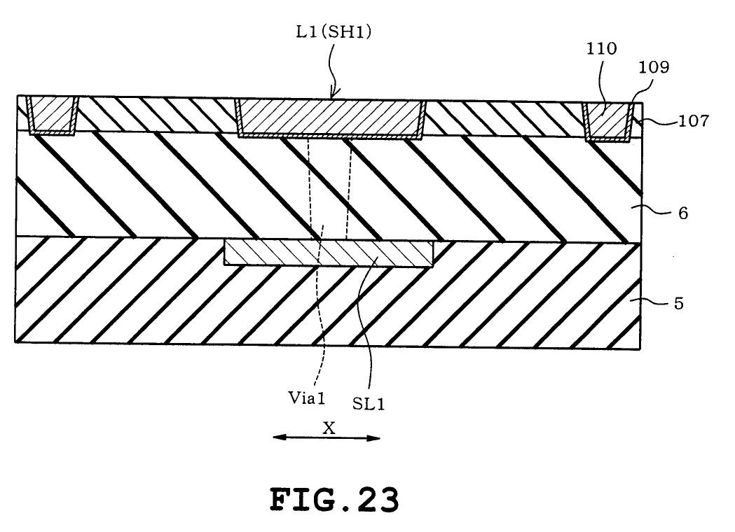

Next, as illustrated in FIG. 23, the upper surface of the silicon oxide film 107 and the upper surfaces of the barrier metal layer 109 and the metal layer 110 are substantially “planarized” by planarizing the barrier metal layer 109 and the metal layer 110 by CMP process. After such process, the second metal interconnect L1 composed of barrier metal layer 109 and the metal layer 110 can be formed as a linear structure extending in the Y-direction. At this time, the second metal interconnect L1 contacting the upper surface of the via plug Via1 serves as the source shunt line SH1.

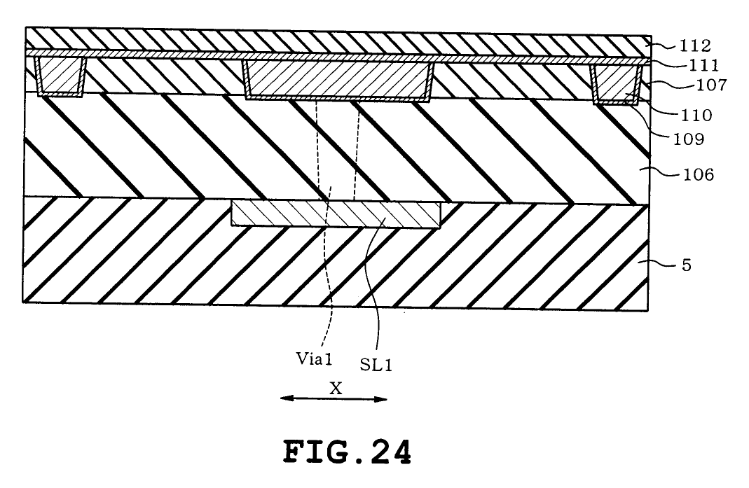

Next, as illustrated in FIG. 24, a silicon nitride film 111 is formed in consistent film thickness on the barrier metal layer 109, metal layer 110, and the silicon oxide film 107 having planarized upper surfaces. The silicon nitride film 111 is provided to restrain upward diffusion of the material (copper) constituting the metal layer 110. Then, a silicon oxide film 112 is formed on the silicon nitride film 111 by dual frequency RF plasma CVD process using TEOS as a source gas.

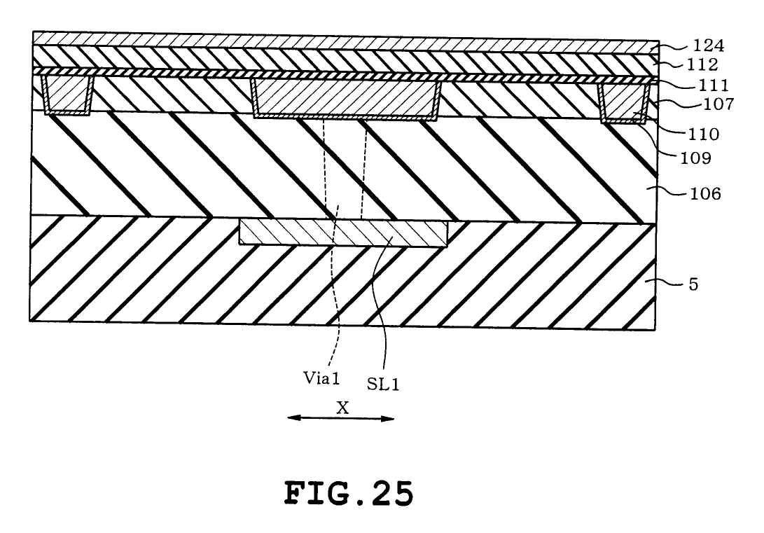

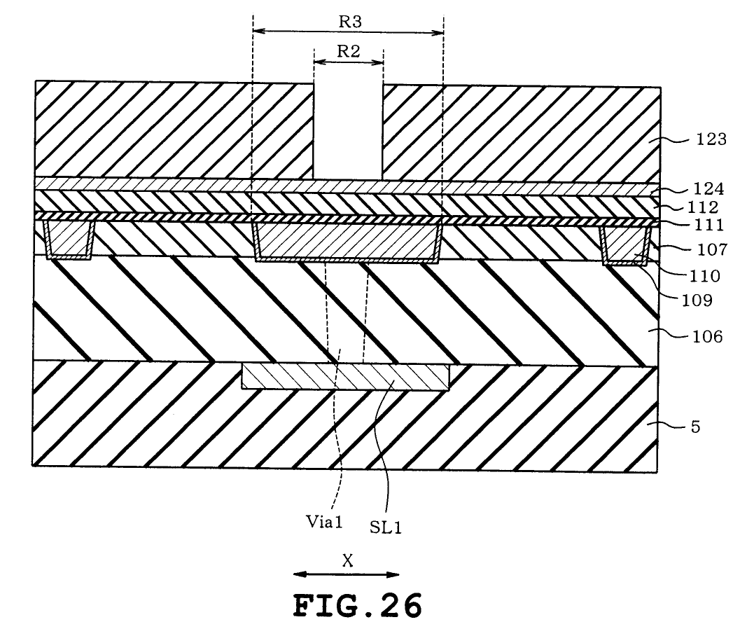

Next, as illustrated in FIG. 25, an antireflective film 124 is formed on the silicon oxide film 112. Then, as shown in FIG. 26, a resist 123 is coated on the antireflective film 124 and thereafter patterned so as to define an opened pattern above the barrier metal layer 109 contacting the upper surface of the via plug Via1 and the metal layer 110. An opening width R2 of the patterned resist 123 is narrower than an X-directional width R3 of the upper surfaces of the barrier metal layer 109 and the metal layer 110.

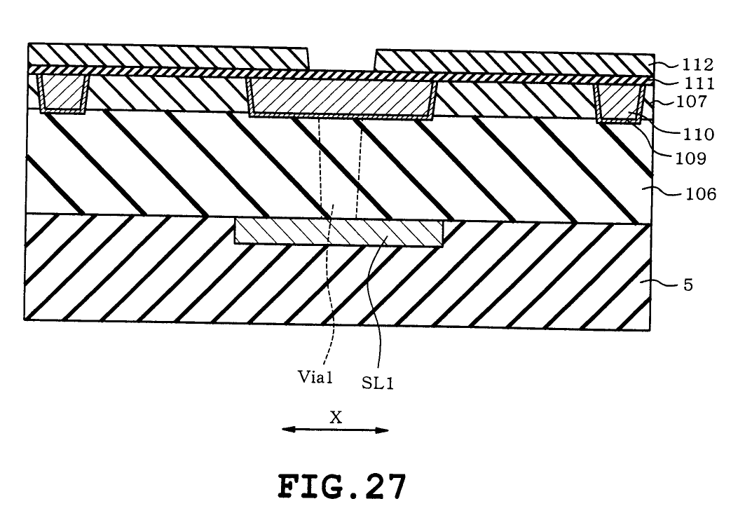

Next, as illustrated in FIG. 27, the antireflective film 124 and the silicon oxide film 112 are etched by RIE process by using the patterned resist 123 as a mask, whereafter the etch process is tentatively stopped. The conditions applied to the etch process in this case is such that the silicon oxide film 112 can be removed by being set with higher selectivity relative to the silicon nitride film 111. Thereafter, the resist 123 and the antireflective film 124 are removed by ashing process.

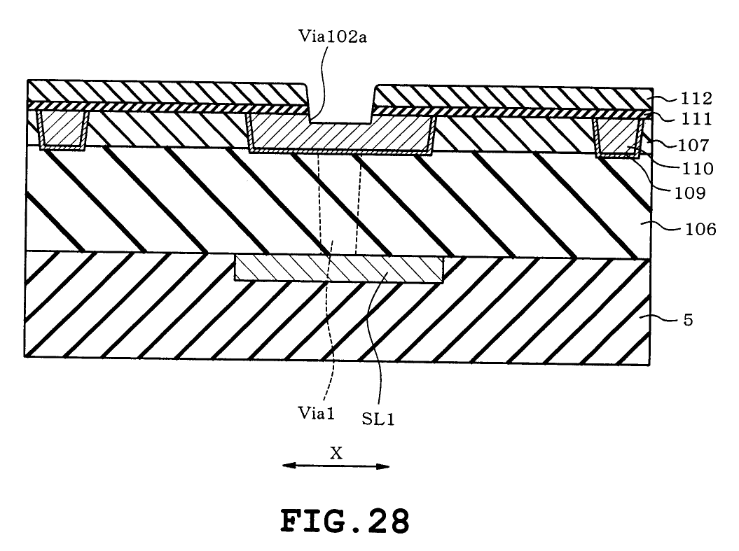

Next, as illustrated in FIG. 28, the etch condition is changed and the silicon nitride film 111 is removed by RIE process by using the silicon oxide film 112 as a mask. The silicon nitride film 111 is etched excessively so that the upper surface of the second metal interconnect L1 is exposed without fail. Consequently, a portion of the upper surface of the metal layer 110 formed immediately under the silicon nitride film 111 is removed to define an upper hole (via hole) Via 102a.

The X-directional width of the bottom (lower end) of the upper hole Via 102a is narrower than the sum of the upper surface film width of the barrier metal layer 109 and the metal layer 110. The depth of the upper hole Via 102a can be controlled by adjusting the etch time.

Also, as illustrated in FIG. 2, the via plug Via2 is provided in a different plane from the via plug Via1. Thus, even if the upper hole Via 102a for forming the via plug Via2 happens to be over-etched to the upper surface height of the silicon oxide film 106, the via plug Via 1 is not affected by such excessive etching.

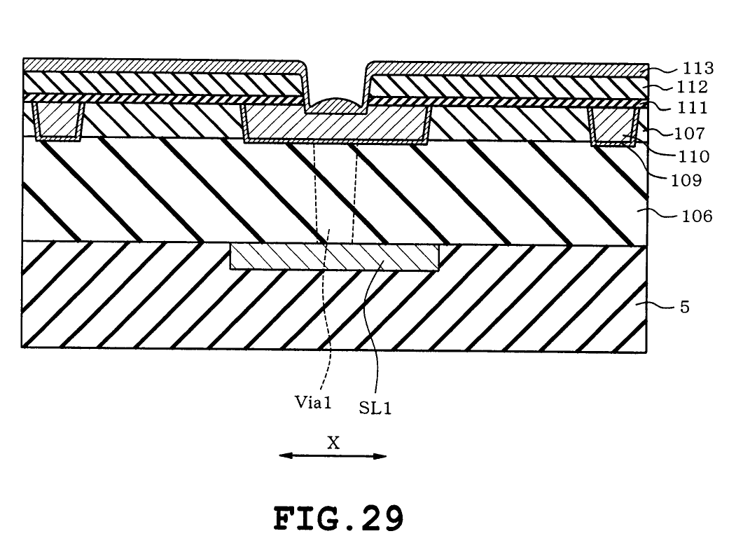

Next, as shown in FIG. 29, a barrier metal layer 113 is formed along the inner surface (inner wall surface and bottom surface) of the upper hole Via 102a. The film thicknesses of the barrier metal layer 113 on the barrier metal layer 109 and the metal layer 110 are inconsistent. Subsequently, as illustrated in FIGS. 3 and 5, the inner side of the barrier metal layer 113 is filled with Al material serving as the metal layer 114. Thus, the multi-layer interconnect structure is formed.

At this time, as described earlier, the following laminated structure (listed in sequence from the lower layer to the upper layer) may be formed: (1) Ti layer 20a/TiOx layer 20b/TiN layer 20c/Ti layer 20d (refer to FIG. 7); (2) Ti layer 21a/TiN layer 21b/TiOx layer 21c/Ti layer 21d (refer to FIG. 8); (3) TiOx layer 22a/Ti layer 22b/TiN layer 22c/Ti layer 22d (refer to FIG. 9); (4) Ti layer 23a/TiN layer 23b/Ti layer 23c/TiOx layer 23d (refer to FIG. 10); and (5) Ti layer 24a/TiOx layer 24b (refer to FIG. 11). The manufacturing method of the above laminated structures will be described hereinafter.

In forming the structure (1) illustrated in FIG. 7, first, Ti layer 20a is formed on the metal layer 10 by sputtering process in the thickness of approximately 35 [nm]. Then, TiOx layer 20b is formed in the upper portion (surface layer) of the Ti layer 20a by thermal processing (at 250° C. for 3 minutes, for example) under oxygen atmosphere. Next, the TiN layer 20c and the Ti layer 20d are formed by sputtering process in the thickness of 35 [nm] and 5 [nm] respectively. Next, the metal layer 14 is formed by filling approximately 650 [nm] of Al material by reflow process.

In forming the structure (2) illustrated in FIG. 8, first, Ti layer 21a and TiN layer 21b are formed sequentially on the metal layer 10 by sputtering process in the thickness of approximately 35 [nm] respectively. Then, TiOx layer 21c is formed in the upper portion (surface layer) of the TiN layer 21b by thermal processing (at 250° C. for 3 minutes, for example) under oxygen atmosphere. Next, Ti layer 21d is formed by sputtering process. Next, the metal layer 14 is formed by filling approximately 650 [nm] of Al material by reflow process.

In forming the structure (3) illustrated in FIG. 9, first, the Ti layer is formed on the metal layer 10 by sputtering process, however; since the exposed surface of the metal layer 10 is naturally oxidized immediately after defining the via hole Via 102a, the TiOx layer 22a is formed in small thickness on the exposed surface of the metal layer 10 by reducing CuOx of the exposed surface of the metal layer 10 by the Ti layer. Thus, the TiOx layer 22a and the Ti layer 22b can be formed immediately above the metal layer 10. Thereafter, the TiN layer 22c and the Ti layer 22d are sequentially formed on the Ti layer 22b by sputtering process in the film thickness of 35 [nm] and 5 [nm]. Next, the metal layer 14 is formed by filling Al material by reflow process.

In forming the structure (4) illustrated in FIG. 10, first the Ti layer 23a and the TiN layer 23b and the Ti layer 23c are formed sequentially on the metal layer 10 by sputtering process in the thickness of approximately 35 [nm], 35 [nm], and 5 [nm] respectively. Then, TiOx layer 23d is formed in the upper portion (surface layer) of the Ti layer 23c by thermal processing (at 250° C. for 3 minutes, for example) under oxygen atmosphere. Next, the metal layer 14 is formed by filling Al material by reflow process.

In forming the structure (5) illustrated in FIG. 11, after forming the Ti layer 24a on the metal layer 10 by sputtering process, TiOx layer 24b is formed in the upper portion (surface layer) of the Ti layer 24a by thermal processing (at 250° C. for 3 minutes, for example) under oxygen atmosphere. Next, the metal layer 14 is formed by filling Al material by reflow process.

Thus, barrier metal layer 113 (corresponding to the barrier metal layer 13) and metal layer 14 can be formed.

According to the present embodiment, since the TiOx layer 20b, 21c, 23d, and 24b are formed by oxidating the Ti layer 20a, 23c, 24a and TiN layer 21b (corresponding to the base layer), increase in resistance of the metal layer 14 by Cu—Al reciprocal diffusion can be prevented.

Also, since the TiOx layer 22a is formed by reducing the naturally oxidized film (corresponding to the oxidized layer) formed on the upper surface of the metal layer 110 after forming the TiOx layer 22a, increase in resistance of the metal layer 14 by Cu—Al reciprocal diffusion can be prevented.

Also, since the silicon nitride film 111 can be formed on the metal layer 10 as a cap film, diffusion of Cu constituting the metal layer 10 can be restrained.

The present disclosure is not to be limited to the aforementioned embodiment, but may be modified or expanded as follows.

A substrate made of other materials may be employed instead of the silicon substrate 2.

The present disclosure may be applied to other semiconductor device having multi-interconnect structure instead of the NAND flash memory device 1.

A cap film 11 formed by silicon nitride film 111 has been described in one embodiment; however, other insulating film materials may be employed instead.

An interlayer insulating film 12 formed by silicon oxide film 112 has been described in one embodiment; however, other insulating film materials may be employed instead.

A barrier metal layer 13 including Ti layer and TiOx (TiO₂) layer has been described in one embodiment; however, the barrier metal layer 13 may assume a structure including a tantalum (Ta) layer and a tantalum oxide (TaOx) layer or a niobium (Nb) layer and a niobium oxide (NbOx) layer.

A metal layer 14 composed of Al material has been described in one embodiment; however, an Al containing layer such as AlCu may be employed instead.

The barrier metal layer 13 may assume the following structure listed in sequence from the copper (Cu) layer side constituting the metal layer 10 to the aluminum (Al) containing layer side constituting the metal layer 14: (6) TiOx layer/Ti layer/TiOx layer/TiN layer/Ti layer, (7) TiOx layer/Ti layer/TiN layer/TiOx layer/Ti layer, and (8) TiOx layer/Ti layer/TiN layer/Ti layer/TiOx layer. The aforementioned effects can be obtained in this case also.

Al material constitutes the metal layer 14 in the upper layer side and Cu material constitutes the metal layer 10 in the lower layer side; however the upper and lower layers may be reversed or disposed laterally. In other words, they may be arranged in any contacting state.

The foregoing description and drawings are merely illustrative of the principles of the present disclosure and are not to be construed in a limited sense. Various changes and modifications will become apparent to those of ordinary skill in the art. All such changes and modifications are seen to fall within the scope of the disclosure as defined by the appended claims.

What is claimed is:

1. A semiconductor device, comprising:
a copper layer;
an aluminum containing layer; and
a barrier metal layer having a laminated structure of a titanium layer and a titanium oxide layer formed between the copper layer and the aluminum containing layer.

2. The device of claim 1, wherein the barrier metal layer is formed in a sequence of titanium layer/titanium oxide layer/titanium nitride layer/titanium layer from the copper layer side to the aluminum containing layer side.

3. A semiconductor device, comprising:
a copper layer;
an aluminum containing layer; and
a barrier metal layer having a laminated structure of a tantalum layer and a tantalum oxide layer or a niobium layer and a niobium oxide layer formed between the copper layer and the aluminum containing layer.

4. A method of manufacturing a semiconductor device, comprising:
forming a copper layer;
forming an interlayer insulating film on the copper layer;
defining a hole penetrating to the copper layer in the interlayer insulating film;
forming a barrier metal layer inside the hole by forming a base layer including at least either titanium, tantalum or niobium, and oxidating the base layer; and
forming aluminum containing layer on the barrier metal layer.

5. A method of manufacturing a semiconductor device, comprising:
forming a copper layer;
forming an interlayer insulating film on the copper layer;
defining a hole penetrating to the copper layer in the interlayer insulating film;
forming a base layer including at least titanium inside the hole;
forming a titanium oxide layer by oxidating the base layer;
forming a titanium nitride layer on the titanium oxide layer;
forming a titanium layer on the titanium nitride layer; and forming aluminum containing layer on the titanium layer.
